(19) United States
(12) Patent Application Publication
(10) Pub. No.: US 2017/0153521 A1
(43) Pub. Date: Jun. 1, 2017

(54) COA ARRAY SUBSTRATE AND LIQUID CRYSTAL PANEL

(71) Applicant: Shenzhen China Star Optoelectronics Technology Co. Ltd., Shenzhen, Guangdong (CN)

(72) Inventor: Xiufen Zhu, Shenzhen City (CN)

(21) Appl. No.: 14/786,161

(22) PCT Filed: Aug. 24, 2015
(86) PCT No.: PCT/CN2015/087958

§ 371 Date: Oct. 21, 2015

(30) Foreign Application Priority Data
Jul. 30, 2015 (CN) 201510460351.5

(51) Int. Cl. G02F 1/1362; G02F 1/1335; G02F 1/1368

(52) U.S. Cl. CPC G02F 1/136227; G02F 1/1368; G02F 1/136209; G02F 1/133514; G02F 2001/136222; G02F 2202/103; G02F 2202/104; G02F 2202/10; H01L 29/7869

(57) ABSTRACT

The present invention provides a COA array substrate and a liquid crystal panel. The COA array substrate comprises a substrate (1), a TFT (T) positioned at a front side of the substrate (1), a passivation protective layer (6) covering the TFT (T), a pixel electrode (7) positioned on the passivation protective layer (6), a black matrix (8) positioned at a back side of the substrate (1) right corresponding to the TFT (T), and a color resist layer (9) covering the black matrix (8) and the back side of the substrate (1); the pixel electrode (7) contacts with the TFT (T) through a via hole (61) penetrating the passivation protective layer (6). In comparison with prior art, the COA array substrate of the present invention can solve the problem that the alignment requirement of traditional array substrate and color filter is high to raise the aperture ratio and can achieve the connection of the pixel electrode and the drain of the TFT without opening holes in the black matrix and the color resist layer. It is easy for manufacture and the light leak can be prevented.

### FIELD OF THE INVENTION

The present invention relates to a display technology field, and more particularly to a COA array substrate and a liquid crystal panel.

### BACKGROUND OF THE INVENTION

With the development of display technology, the flat panel device, such as Liquid Crystal Display (LCD) possesses advantages of high image quality, power saving, thin body and wide application scope. Thus, it has been widely applied in various consumer electrical products, such as mobile phone, television, personal digital assistant, digital camera, notebook, laptop, and becomes the major display device.

Most of the liquid crystal displays on the present market are backlight type liquid crystal displays, which comprise a liquid crystal display panel and a backlight module. Generally, the liquid crystal display panel comprises a Color Filter (CF), a Thin Film Transistor Array Substrate (TFT Array Substrate) and a Liquid Crystal Layer positioned between the two substrates. The working principle is that the light of backlight module is reflected to generate images by applying driving voltages to the two glass substrate for controlling the rotations of the liquid crystal molecules.

Generally, in the traditional liquid crystal panel, a Black Matrix (BM) is manufactured at one side of the color filter, which comprises a color resist layer having red, green, blue color resists and a common electrode, and a TFT and a pixel electrode are manufactured at one side of the array substrate. Such traditional liquid crystal panel is restricted by the alignment accuracy of the array substrate and the color filter, and thus the aperture ratio of the pixel is influenced.

For solving the problem that alignment requirement of traditional array substrate and color filter is too high to raise the aperture ratio, the color resist layer can be manufactured at one side of the array substrate, i.e. utilizing the COA (Color Filter On Array) technology.

In the present COA array substrate of main stream, the black matrix and the color resist layer are generally manufactured under the pixel electrode, and the specific structure is shown in FIG. 1, which comprises a substrate 100, a color resist layer 700 and a black matrix 800 positioned at a front side of the substrate 100, a passivation protective layer 900 positioned on the black matrix 800 and a pixel electrode 1000 positioned on the passivation protective layer 900. The pixel electrode 1000 contacts with the drain of the TFT through a via hole 987 penetrating the passivation protective layer 900, the black matrix 800 and the color resist layer 700.

Because the thicknesses of the black matrix 800 and the color resist layer 700 are larger than the thicknesses of other film layers, and the via hole 987 penetrating the passivation protective layer 900, the black matrix 800 and the color resist layer 700 is more difficult to be manufactured, the dimension of the via hole 987 is not easy to be accurately controlled, and meanwhile, the height difference of the bottom and the top of the via hole 987 is larger, which can easily cause the bad alignment of the area corresponded with the via hole 987, and the light leak can easily generate.

### SUMMARY OF THE INVENTION

An objective of the present invention is to provide a COA array substrate, which can solve the problem that the alignment requirement of traditional array substrate and color filter is high, and it is easy for manufacture and the light leak can be prevented.

Another objective of the present invention is to provide a liquid crystal panel, of which the aperture ratio is high and it is easy for manufacture.

For realizing the aforesaid objectives, the present invention provides a COA array substrate, comprising a substrate, a TFT positioned at a front side of the substrate, a passivation protective layer covering the TFT, a pixel electrode positioned on the passivation protective layer, a black matrix positioned at a back side of the substrate right corresponding to the TFT, and a color resist layer covering the black matrix and the back side of the substrate;

the pixel electrode contacts with the TFT through a via hole penetrating the passivation protective layer.

The TFT comprises a gate positioned at the front side of the substrate, a gate isolation layer covering the gate and the front side of the substrate, a semiconductor layer positioned on the gate isolation layer above the gate, and a source and a drain positioned on the gate isolation layer which respectively contact with two sides of the semiconductor layer;

the passivation protective layer covers the source, drain, semiconductor layer and gate isolation layer; the pixel electrode contacts with the drain of the TFT through a via hole penetrating the passivation protective layer.

Material of the black matrix is Acrylic black resist.

The color resist layer at least comprises red color resist, green color resist and blue color resist.

The substrate is a glass substrate.

Material of the gate, source and the drain is a stack combination of one or more of molybdenum, titanium, aluminum, copper and nickel.

Material of the gate isolation layer and the passivation protective layer is Silicon Oxide, Silicon Nitride, or a combination of the two.

Material of the pixel electrode is ITO.

Material of the semiconductor layer is one of amorphous silicon semiconductor, Low Temperature Poly-silicon semiconductor and metal oxide semiconductor.

The present invention further provides a liquid crystal panel, comprising an array substrate, a color filter and a liquid crystal layer positioned between the array substrate and the color filter, wherein the array substrate is the aforesaid COA array substrate.

The benefits of the present invention: the present invention provides a COA array substrate and a liquid crystal panel. The black matrix is positioned at the back side of the substrate, and the TFT, the passivation protective layer and the pixel electrode are positioned at the front side of the substrate. The pixel electrode contacts with the TFT through the via hole penetrating the passivation protective layer. In comparison with prior art, the COA array substrate of the present invention can solve the problem that the alignment requirement of traditional array substrate and color filter is high to raise the aperture ratio and can achieve the connection of the pixel electrode and the drain of the TFT without opening holes in the black matrix and the color resist layer. It is easy for manufacture and the light leak can be prevented.

In order to better understand the characteristics and technical aspect of the invention, please refer to the following detailed description of the present invention is concerned with the diagrams, however, provide reference to the accompanying drawings and description only and is not intended to be limiting of the invention.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a structure diagram of a COA array substrate according to prior art;

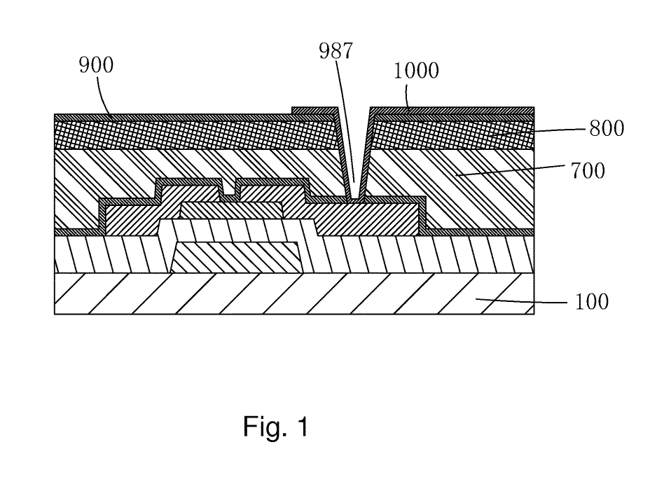

FIG. 2 is a structure diagram of a COA array substrate according to the present invention.

### DETAILED DESCRIPTION OF PREFERRED EMBODIMENTS

For better explaining the technical solution and the effect of the present invention, the present invention will be further described in detail with the accompanying drawings and the specific embodiments.

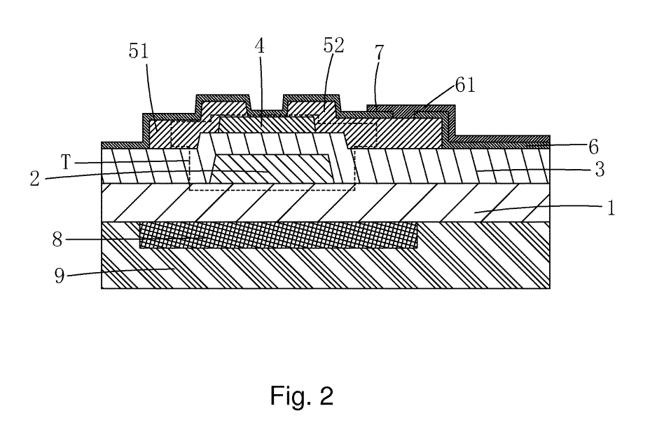

Please refer to FIG. 2. The present invention provides a COA array substrate, comprising a substrate 1, a TFT T positioned at a front side of the substrate 1, a passivation protective layer 6 covering the TFT T, a pixel electrode 7 positioned on the passivation protective layer 6, a black matrix 8 positioned at a back side of the substrate 1 right corresponding to the TFT T, and a color resist layer 9 covering the black matrix 8 and the back side of the substrate 1; the pixel electrode 7 contacts with the TFT T through a via hole 61 penetrating the passivation protective layer 6.

Because the black matrix 8 is positioned at the back side of the substrate 1 right corresponding to the TFT T, and the color resist layer 9 covers the black matrix 8 and the back side of the substrate 1, the problem that the alignment requirement of traditional array substrate and color filter is high can be solved to prevent the misalignment in the assembly process to raise the aperture ratio.

Specifically, the TFT T comprises a gate 2 positioned at the front side of the substrate 1, a gate isolation layer 3 covering the gate 2 and the front side of the substrate 1, a semiconductor layer 4 positioned on the gate isolation layer 3 above the gate 2, and a source 51 and a drain 52 positioned on the gate isolation layer 3 which respectively contact with two sides of the semiconductor layer 4.

The passivation protective layer 6 covers the source, 51, drain 52, semiconductor layer 4 and gate isolation layer 3. The pixel electrode 7 contacts with the drain 52 of the TFT T through a via hole 61 penetrating the passivation protective layer 6. Because the pixel electrode 7 can contact with the drain 52 of the TFT T merely through the via hole 61 penetrating the passivation protective layer 6 and opening holes in the black matrix and the color resist layer in the COA array substrate according to prior art is not required, and the thickness of the passivation protective layer 6 is smaller and opening holes is easier, the dimension of the via hole 61 is easy for control which is more accurate, and the height difference of the bottom and the top of the via hole 61 is smaller which can ensure the normal alignment of the area corresponded with the via hole 61, and light leak is difficult to generate.

Material of the black matrix 8 is Acrylic black resist.

The color resist layer 9 at least comprises red color resist, green color resist and blue color resist. The white color resist or the yellow color resist can be added on the display demands.

The substrate 1 is a glass substrate.

Material of the gate 2, source 51 and the drain 52 is a stack combination of one or more of one or more of molybdenum (Mo), titanium (Ti), aluminum (Al), copper (Cu) and nickel (Ni).

Material of the gate isolation layer 3 and the passivation protective layer 6 is Silicon Oxide (SiOx), Silicon Nitride (SiNx) or a combination of the two.

Material of the pixel electrode 7 is Indium Tin Oxide (ITO).

Material of the semiconductor layer 4 is one of amorphous silicon semiconductor, Low Temperature Poly-silicon semiconductor and metal oxide semiconductor.

The present invention further provides a liquid crystal panel, comprising an array substrate, a color filter and a liquid crystal layer positioned between the array substrate and the color filter, wherein the array substrate is the aforesaid COA array substrate shown in FIG. 2. The description is not repeated here.

In conclusion, in the COA array substrate and the liquid crystal panel of the present invention, the black matrix is positioned at the back side of the substrate, and the TFT, the passivation protective layer and the pixel electrode are positioned at the front side of the substrate. The pixel electrode contacts with the TFT through the via hole penetrating the passivation protective layer. In comparison with prior art, the COA array substrate of the present invention can solve the problem that the alignment requirement of traditional array substrate and color filter is high to raise the aperture ratio and can achieve the connection of the pixel electrode and the drain of the TFT without opening holes in the black matrix and the color resist layer. It is easy for manufacture and the light leak can be prevented.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A COA array substrate, comprising a substrate, a TFT positioned at a front side of the substrate, a passivation protective layer covering the TFT, a pixel electrode positioned on the passivation protective layer, a black matrix positioned at a back side of the substrate right corresponding to the TFT, and a color resist layer covering the black matrix and the back side of the substrate;
the pixel electrode contacts with the TFT through a via hole penetrating the passivation protective layer.

2. The COA array substrate according to claim 1, wherein the TFT comprises a gate positioned at the front side of the substrate, a gate isolation layer covering the gate and the front side of the substrate, a semiconductor layer positioned on the gate isolation layer above the gate, and a source and a drain positioned on the gate isolation layer which respectively contact with two sides of the semiconductor layer;
the passivation protective layer covers the source, drain, semiconductor layer and gate isolation layer; the pixel electrode contacts with the drain of the TFT through a via hole penetrating the passivation protective layer.

3. The COA array substrate according to claim 1, wherein material of the black matrix is Acrylic black resist.

4. The COA array substrate according to claim 1, wherein the color resist layer at least comprises red color resist, green color resist and blue color resist.

5. The COA array substrate according to claim 1, wherein the substrate is a glass substrate.

6. The COA array substrate according to claim 2, wherein material of the gate, source and the drain is a stack combination of one or more of molybdenum, titanium, aluminum, copper and nickel.

7. The COA array substrate according to claim 2, wherein material of the gate isolation layer and the passivation protective layer is Silicon Oxide, Silicon Nitride, or a combination of the two.

8. The COA array substrate according to claim 2, wherein material of the pixel electrode is ITO.

9. The COA array substrate according to claim 2, wherein material of the semiconductor layer is one of amorphous silicon semiconductor, Low Temperature Poly-silicon semiconductor and metal oxide semiconductor.

10. A liquid crystal panel, comprising an array substrate, a color filter and a liquid crystal layer positioned between the array substrate and the color filter, wherein the array substrate is a COA array substrate, comprising a substrate, a TFT positioned at a front side of the substrate, a passivation protective layer covering the TFT, a pixel electrode positioned on the passivation protective layer, a black matrix positioned at a back side of the substrate right corresponding to the TFT, and a color resist layer covering the black matrix and the back side of the substrate;
the pixel electrode contacts with the TFT through a via hole penetrating the passivation protective layer.

11. The liquid crystal panel according to claim 10, wherein the TFT comprises a gate positioned at the front side of the substrate, a gate isolation layer covering the gate and the front side of the substrate, a semiconductor layer positioned on the gate isolation layer above the gate, and a source and a drain positioned on the gate isolation layer which respectively contact with two sides of the semiconductor layer;
the passivation protective layer covers the source, drain, semiconductor layer and gate isolation layer; the pixel electrode contacts with the drain of the TFT through a via hole penetrating the passivation protective layer.

12. The liquid crystal panel according to claim 10, wherein material of the black matrix is Acrylic black resist.

13. The liquid crystal panel according to claim 10, wherein the color resist layer at least comprises red color resist, green color resist and blue color resist.

14. The liquid crystal panel according to claim 10, wherein the substrate is a glass substrate.

15. The liquid crystal panel according to claim 11, wherein material of the gate, source and the drain is a stack combination of one or more of molybdenum, titanium, aluminum, copper and nickel.

16. The liquid crystal panel according to claim 11, wherein material of the gate isolation layer and the passivation protective layer is Silicon Oxide, Silicon Nitride, or a combination of the two.

17. The liquid crystal panel according to claim 11, wherein material of the pixel electrode is ITO.

18. The liquid crystal panel according to claim 11, wherein material of the semiconductor layer is one of amorphous silicon semiconductor, Low Temperature Poly-silicon semiconductor and metal oxide semiconductor.
